(19) United States
(12) Patent Application Publication
(10) Pub. No.: US 2025/0279236 A1
(43) Pub. Date: Sep. 4, 2025

(54) TRANSFORMER WITH SPIRAL INDUCTORS

(71) Applicant: UNIVERSITY OF LIMERICK, Limerick (IE)

(72) Inventors: Pat Meehan, Limerick (IE); Karl Rinne, Cork (IE)

(21) Appl. No.: 18/291,872

(22) PCT Filed: Jul. 28, 2022
(86) PCT No.: PCT/EP2022/071277

§ 371 Date: Jan. 24, 2024

(30) Foreign Application Priority Data
Jul. 28, 2021 (GB) 2110822.0

(51) Int. Cl. H01F 30/06; H01F 27/28

(52) U.S. Cl. CPC H01F 30/06; H01F 27/2804; H01F 27/288; H01F 2027/2809

(57) ABSTRACT

Disclosed is a transformer that includes a primary spiral inductor, and a secondary spiral inductor magnetically coupled to the primary spiral inductor, wherein a physical location of the secondary spiral inductor is at an offset relative to the primary spiral inductor to reduce interwinding capacitance between the primary and secondary spiral inductors, while decreasing a magnetic coupling between the primary and secondary spiral inductors to a lesser extent.

### CLAIM OF PRIORITY

This application is the U.S. National Stage of International Patent Application No. PCT/EP2022/071277 filed 28 Jul. 2022, which claims priority to UK Patent Application No. GB 2110822.0 filed 28 Jul. 2021, the entire content of these applications being incorporated herein by reference as if fully set forth below in its entirety and for all applicable purposes.

### FIELD

The present disclosure relates to a spiral inductor, and a transformer formed using such spiral inductors. More particularly, the present disclosure relates to improving Q-factor of a spiral inductor, and/or transformers.

### BACKGROUND

FIG. 1 illustrates a conventional spiral planar-inductor 100 that can be used as an individual inductor and also be used to form a transformer. The spiral planar inductor 100 uses a constant-width track to create a planar inductor or a transformer.

It is known, that at least two spiral planar inductors 100 may be stacked vertically such that the tracks overlap with each other in order to construct a transformer. Further, the spiral planar inductor 100 may be implemented on a printed circuit board or enclosed within an integrated circuit package or fabricated on a semiconductor die. Furthermore, the spiral planar inductor 100 may be used in circuits operating at radio frequencies and/or in power electronic circuits. Furthermore, the spiral planar inductor 100 may be implemented in various shapes including but not limited to: a square, polygonal, circular, or elliptical shape.

The inductance L (μH) of the spiral planar inductor 100 may be estimated according to the following known Wheeler's Equation:

$$L ( μ H ) = \frac{{A}^{2} {n}^{2}}{8 A + 11 B} \qquad ( 1 )$$

where,
n is the number of turns in the spiral coil
A is the length (in inches) of half way into the spiral turns
B is the width (in inches) of the entire spiral coil from first to last turn

As seen from the equation (1), the length (A) appears in the numerator as a squared term and in the denominator as a linear term. Thus, increase in length (A) beyond a certain value have a positive effect on inductance and vice versa. The increase in width (B) decreases inductance as it is in the denominator as a linear term. The number of turns (n) is squared in the numerator, thus, more turns leads to a squared increase in inductance. However, increase in number of turns causes a decrease in the length (A), which may or may not be beneficial.

The inductance of a single conductor of a rectangular section may be given by the following equation:

$$L ( {10}^{- 7} ) H = \text{?} ( ln ( \frac{\text{?}}{W + H} \} - ln ( δ ) + \frac{\text{?}}{2} ) \qquad ( 2 )$$

$$\text{?} \text{indicates text missing or illegible when filed}$$

Where,
Large L—Inductance
Small I—side length
W—track width
H—height (not shown)

The inductance of the single conductor may be useful to view each single turn of the spiral planar inductor 100 alone. It would not however be accurate to just sum the individual inductances from Equation 2 to get the total inductance as given by Equation 1 because the mutual inductance between turns comes into play.

As seen from the equation (2), a longer piece gives more inductance than a shorter one, but the relationship is not linear. Also, the inductance is the natural log term of the ratio of the conductor length (I) to width (W) added to height (H). The natural log term has the effect of diminishing returns as the operand increases in size. As the width plus height (W+H) decreases relative to the length (I), the resulting increase in inductance (L) diminishes. Therefore, for the spiral planar inductor 100, the outer, narrower turns have less self-inductance relative to their length compared to the inner turns.

Below Table I illustrates various dimensions of the spiral planar inductor 100 for a fixed track width (W=600 μm), a fixed track height (H=0.58 μm) and the metal as aluminium.

TABLE I

| | Side | Total | CSA | Resis- | Resis- | | |
|---|---|---|---|---|---|---|---|
| Turn # | length(m) | length (m) | (m²) | tance (Ω) | tance (Ω) | Length/Width | In(L/W) |
| 1 | 0.003 | 0.01 | 3.5E−10 | 0.9 | 0.9 | 20 | 3.0 |
| 2 | 0.006 | 0.02 | 3.5E−10 | 1.8 | 2.7 | 40 | 3.7 |
| 3 | 0.012 | 0.05 | 3.5E−10 | 3.7 | 6.4 | 80 | 4.4 |
| 4 | 0.024 | 0.10 | 3.5E−10 | 7.3 | 13.7 | 160 | 5.1 |
| 5 | 0.048 | 0.19 | 3.5E−10 | 14.6 | 28.3 | 320 | 5.8 |
| 6 | 0.096 | 0.38 | 3.5E−10 | 29.2 | 58 | 640 | 6.5 |
| 7 | 0.192 | 0.77 | 3.5E−10 | 58 | 116 | 1280 | 7.2 |
| 8 | 0.384 | 1.64 | 3.5E−10 | 117 | 233 | 2560 | 7.8 |
| 9 | 0.786 | 3.07 | 3.5E−10 | 234 | 467 | 5120 | 8.5 |
| 10 | 1.538 | 8.14 | 3.5E−10 | 468 | 935 | 10240 | 9.2 |

The turn circumferences, cross sectional areas (CSA) and resulting resistances are estimated using the length. As can be seen from Table I, the cumulative resistance per turn varies from 0.9Ω to 935Ω for turns 1 to 10 respectively. Further, the ratios of lengths to widths (L/W) range from 20 to 10,240 from innermost turn to outermost turn. However, taking the natural log of the ratios, as per Equation 2, the resulting scale is only from 3 to 9.2. Therefore, the inductance benefit from increasing the resistance by a factor of one thousand is limited by the natural log term of l/w which only increases by a factor of three.

Further, the quality factor (Q factor) of the spiral planar inductor 100 may be represented by the following equation:

$$Qfactor = \frac{2 π fL}{R} \qquad ( 3 )$$

where, f is the frequency, L is the inductance and R is the resistance.

The Q factor the spiral planar inductor 100 is effectively a ratio of energy stored in the inductance to energy lost in the resistance of the spiral inductor 100, and is a measure of the performance of a coil, at least in terms of its losses and frequency response.

As seen in Table I in the calculated total resistance of the spiral planar inductor 100 at 5^{th} turn is 28.30. The total inductance at 5^{th} turn estimated using equation 1 is 364 nH. Further, the Q-factor estimated at 60 Hz using equation 3 is 13. Thus, it is apparent that as the inductance is desired to be increased i.e. if more turns are added to the spiral planar inductor 100, the resistance of the spiral planar inductor 100 increases and there is a loss in terms of quality factor and/or energy efficiency of the spiral planar inductor 100. This is also true for a transformer constructed using a plurality of said planar inductor coils stacked vertically. Further, such transformers constructed using said planar inductors suffer from capacitive coupling between the planar coils of the inductor thereby causing undesired effect.

Therefore, there is an unfulfilled and unresolved need in the art for a spiral planar inductor and a transformer with an improved Q factor and that overcomes the limitations associated with existing spiral planar inductors and transformers.

### SUMMARY

According to the present invention there is provided a transformer and a width-modulated spiral inductor, as set out in the appended claims.

In one embodiment there is provided a width-modulated spiral inductor, comprising a plurality of turns arranged in a substantially planar manner, wherein each turn has a width different from a width of another turn.

In one embodiment a first turn of the plurality of turns has a predefined length and width, and a length and width of each turn subsequent to the first turn is obtained by multiplying a length and a width of corresponding previous turn by a predetermined ratio, such that resistance-per-turn remains constant.

Various embodiments of the present invention disclose that when the width of a track of a spiral inductor is varied to a specific formula along the spiral length, the Q factor is significantly improved. Also, inter-winding capacitance is significantly reduced in transformers formed using such width-modulated spiral inductors, specifically, by arranging the width-modulated spiral inductors at an offset from each other.

In one embodiment the variable width of the plurality of turns modulates a ratio of overall inductance to overall resistance of the width-modulated spiral inductor.

In one embodiment a pre-defined number of inner turns of the plurality of turns have a width smaller than a pre-defined average width, and a pre-defined number of outer turns of the plurality of turns have a width greater than the pre-defined average width.

In one embodiment the magnetic field strength of the width-modulated spiral inductor is unevenly distributed across the plurality of turns, such that magnetic flux density of the width-modulated spiral inductor is concentrated across a pre-defined number of turns.

In a further embodiment there is provided a transformer comprising:
a primary spiral inductor; and
a secondary spiral inductor magnetically coupled to the primary spiral inductor, wherein a physical location of the secondary spiral inductor is at an offset relative to the primary spiral inductor to reduce interwinding capacitance between the primary and secondary spiral inductors, while decreasing a magnetic coupling between the primary and secondary spiral inductors to a pre-defined extent.

In one embodiment the primary and secondary spiral inductors are spaced apart and stacked vertically in a staggered manner, such that at least one turn of the primary spiral inductor does not overlap with at least one turn of the secondary spiral inductor.

In one embodiment each of the primary and secondary spiral inductors is a constant-width spiral inductor, wherein the constant-width spiral inductor includes a plurality of turns of a constant width.

In one embodiment each of the primary and secondary spiral inductors is a width-modulated spiral inductor, wherein the width-modulated spiral inductor includes a plurality of turns arranged in a substantially planar manner, and wherein each turn has a width different from a width of another turn.

In one embodiment a first turn of the plurality of turns has a predefined length and width, and a length and width of each turn subsequent to the first turn is obtained by multiplying a length and a width of corresponding previous turn by a predetermined ratio, such that resistance-per-turn of the width-modulated spiral inductor remains constant.

In one embodiment the magnetic field strength of the width-modulated spiral inductor is unevenly distributed across the plurality of turns, such that magnetic flux density of the width-modulated spiral inductor is concentrated across a pre-defined number of turns.

In one embodiment the width of each turn and the offset between the primary and secondary spiral inductors is determined so as to maximise the magnetic flux density and minimize capacitive coupling across the pre-defined number of turns.

In one embodiment a track to track space between the primary and secondary spiral inductors is modulated along a length of the transformer to enable even spread of the interwinding capacitance along the length of the transformer.

In one embodiment, the primary and secondary spiral inductors are fabricated as top and bottom layers respectively on a silicon substrate, in a manner such that the secondary spiral inductor sits in one or more gaps between turns of the primary spiral inductor, and wherein a conductive shield layer is provided beneath the primary and secondary spiral inductors, to prevent formation of a capacitance path from the primary spiral inductor down to the silicon substrate, across the silicon substrate and then back up to the secondary spiral inductor.

In one embodiment, the primary spiral inductor is formed from a thick metal layer, the secondary spiral inductor coil is formed from thick metal oxide layers, and the conductive shield layer is formed by diffusing one of p and n layers into the silicon substrate.

### BRIEF DESCRIPTION OF THE DRAWINGS

The invention will be more clearly understood from the following description of an embodiment thereof, given by way of example only, with reference to the accompanying drawings, in which:—

FIG. 1 illustrates a conventional spiral inductor;

FIG. 2 illustrates a width-modulated spiral inductor, in accordance with an embodiment of the present invention;

FIGS. 3A and 3B illustrate comparative plots of magnetic field strength (H) plotted along the X axis for the conventional spiral inductor and the width modulated spiral inductor respectively;

FIGS. 4A and 4B illustrate conventional spiral inductor and more hollow width-modulated spiral inductor respectively;

FIGS. 4C and 4D illustrate comparative plot of magnetic field strength (H) plotted along the X axis for the conventional spiral inductor and more hollow width-modulated spiral inductors of FIGS. 4A and 4B;

FIG. 5A illustrates a conventional spiral transformer having a normal, vertical planar spiral transformer design;

FIG. 5B illustrates a spiral transformer in which conventional spiral inductors are at an offset with respect to each other, in accordance with an embodiment of the present invention;

FIGS. 6A-6C illustrate various types of width modulated spiral transformers, in accordance with various embodiments of the present invention;

FIGS. 7A and 7B illustrate two transformers formed using conventional and width modulated spiral inductors respectively, in which respective inductors are at an offset from each other, in accordance with various embodiments of the present invention;

FIG. 8A illustrates a transformer that includes two width-modulated spiral inductors that are at an offset from each other, and a shield layer in the capacitance path of the inductors, in accordance with an embodiment of the present invention;

FIG. 8B illustrates fabrication of the transformer of FIG. 8A on a silicon substrate, in accordance with an embodiment of the present invention;

FIG. 9A illustrates a basic block diagram of a circuit using a width-modulated transformer, in accordance with an embodiment of the present invention; and

FIG. 9B illustrates a diagrammatic representation of inter-winding capacitance varying with track to track space in physical layout of the width-modulated transformer, in accordance with an embodiment of the present invention.

### DETAILED DESCRIPTION OF DRAWINGS

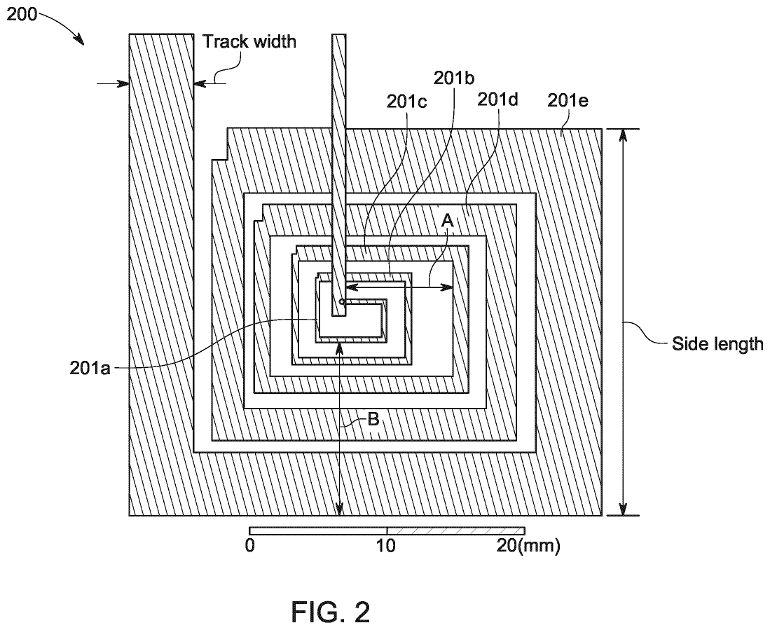

FIG. 2 illustrates a width-modulated spiral inductor 200 in accordance with an embodiment of the present invention. The width-modulated spiral inductor 200 includes a plurality of turns (201a-201e) arranged in substantially planar manner forming an inductor. In the width modulated spiral inductor 200, each turn can have a width different from a width of another turn.

Below table II illustrates various dimensions of the width-modulated spiral inductor 200.

TABLE II

| | Side | Total | Width | CSA | Resis- | Σ Resis- | | |
|---|---|---|---|---|---|---|---|---|
| Turn # | length(m) | length (m) | (m) | (m²) | tance (Ω) | tance (Ω) | Length/Width | In(L/W) |
| 1 | 0.0030 | 0.01 | 3.00E−04 | 1.7E−10 | 1.8 | 1.8 | 40.0 | 3.7 |
| 2 | 0.0080 | 0.02 | 6.00E−04 | 3.5E−10 | 1.8 | 3.7 | 40.0 | 3.7 |
| 3 | 0.0120 | 0.05 | 1.20E−03 | 7.0E−10 | 1.8 | 5.5 | 40.0 | 3.7 |
| 4 | 0.0240 | 0.10 | 2.40E−03 | 1.4E−09 | 1.8 | 7.3 | 40.0 | 3.7 |
| 5 | 0.0460 | 0.19 | 4.80E−03 | 2.8E−09 | 1.8 | 9.1 | 40.0 | 3.7 |
| 6 | 0.0960 | 0.38 | 9.60E−03 | 5.6E−09 | 1.8 | 11.0 | 40.0 | 3.7 |
| 7 | 0.1920 | 0.77 | 1.92E−02 | 1.1E−08 | 1.8 | 12.8 | 40.0 | 3.7 |
| 8 | 0.3840 | 1.54 | 3.84E−02 | 2.2E−08 | 1.8 | 14.6 | 40.0 | 3.7 |
| 9 | 0.7860 | 3.07 | 7.68E−02 | 4.5E−06 | 1.6 | 16.4 | 40.0 | 3.7 |
| 10 | 1.5360 | 6.14 | 1.54E−01 | 8.9E−06 | 1.6 | 16.3 | 40.0 | 3.7 |

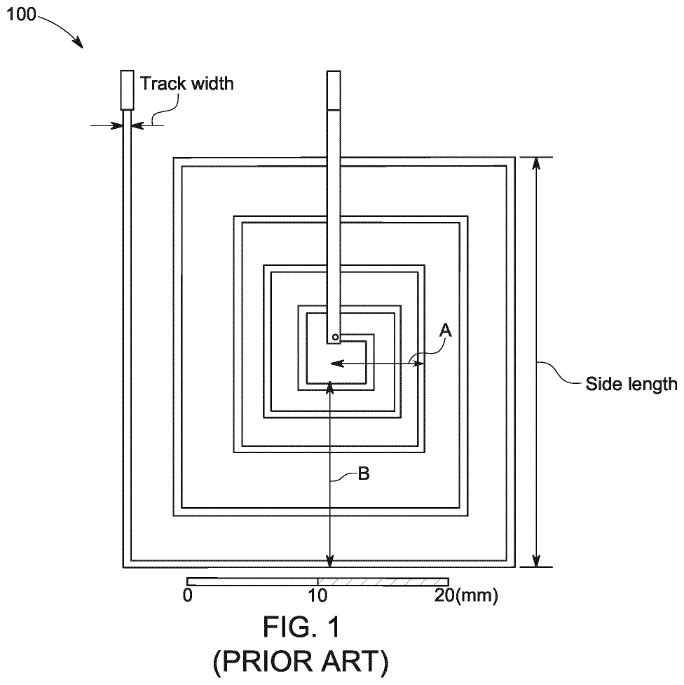

The width-modulated spiral inductor 200 has a number of turns (n) and an overall area similar to that of the conventional spiral planar inductor 100 (for example, see FIG. 1), but variable track width with respect to the spiral planar inductor 100.

For example, referring to Table II, the width of the first turn 201a is initially set to be 0.003 m which is half of width of each turn of the conventional spiral inductor 100. The width of each subsequent turn of the width modulated spiral inductor 200 is obtained by multiplying a width of corresponding previous turn by a predetermined ratio. In an example, when the predetermined ratio is 2, then the width of 2^{nd} turn 201b is twice the width of the first turn 201a, i.e. 0.006 m The width of 3^{rd} turn 201c is twice of that of the second turn 201b, i.e. 0.012 m, and so on.

Furthermore, referring to Table II, the length of the first turn 201a is initially set to be of a predetermined value, for example, 0.0030 m. The length of each subsequent turn of the width modulated spiral inductor 200 is obtained by multiplying a length of corresponding previous turn by the predetermined ratio. In an example, when the predetermined ratio is 2, then the length of 2^{nd} turn 201b is twice the length of the first turn 201a, i.e. 0.060 m. The width of 3^{nd} turn 201c is twice the width of the second turn 201b, i.e. 0.0120 m, and so on.

Furthermore, referring to Table II, since the same predetermined ratio is applied to both the length and width of each turn, the resistance of each turn stays constant throughout, for example, 1.8Ω.

Furthermore, referring to Table II, since the same predetermined ratio is applied to both the length and width of each turn, the natural log term of L/W (also hereinafter referred to as inductance factor) also remains constant for each turn. Therefore, the inductance benefit from increasing the resistance is no more limited by the natural log term of LAW and the inner turns have increased quality factor. Referring to Tables I and II together, the outermost tenth turn of the conventional planar inductor 100 has a cumulative resistance ΣΩ as 10,240 and the inductance factor as 9.2, whereas the tenth turn of the width-modulated spiral inductor 200 has a cumulative resistance ΣΩ as 18.3 and the inductance factor as 3.7. Thus, the outermost 10^{th} turn of the width-modulated spiral inductor 200 has (18.3/10,240)= 1/559th the resistance of the conventional inductor 100 but the inductance factor of the inductor 200 only drops to 3.7/9.2=1/2.5th the inductance factor of the conventional planar inductor 100. This predicts that varying the spiral width in such a fashion presents the option for decreased undesired resistance without the same decrease in desired inductance.

However, narrower inner-turns suggests that more turns can be fitted in the given space. This would increase the total number of turns, n, in Equation 1, giving a squared law increase in inductance. However, the A dimension may also decrease as the distance to the middle turn has decreased. This may counter the effect of increased n. Furthermore, the innermost turns may be close enough to the origin that the current flowing in the opposite leg with a counter flow magnetic field may act to cancel out the inductance of the entire turn.

It may be noted that Equation 2 may not be used to estimate the overall inductance of the width modulated spiral inductor 200 as the width term is a variable. An exemplary Ansys Maxwell simulator has been used to determine the inductance and resistance for 5^{th} turn as 240 nH and 9.50 respectively. The simulated resistance is very close to the 9.10 predicted in Table II. For the calculated inductance and resistance values, at 60 Hz, the Q-factor for the width-modulated spiral inductor 200 is estimated to be 25.26, as compared to 15.2 of the conventional spiral planar inductor 100. Thus, the width-modulated spiral inductor 200 has a significantly improved Q-factor as compared to that of the conventional spiral planar inductor 100.

Although, Table II illustrates various dimensions of the width-modulated spiral inductor 200 by assuming the predetermined ratio as 2, it would be apparent to one of ordinary skill in the art, that the predetermined ratio can have any value greater than unity.

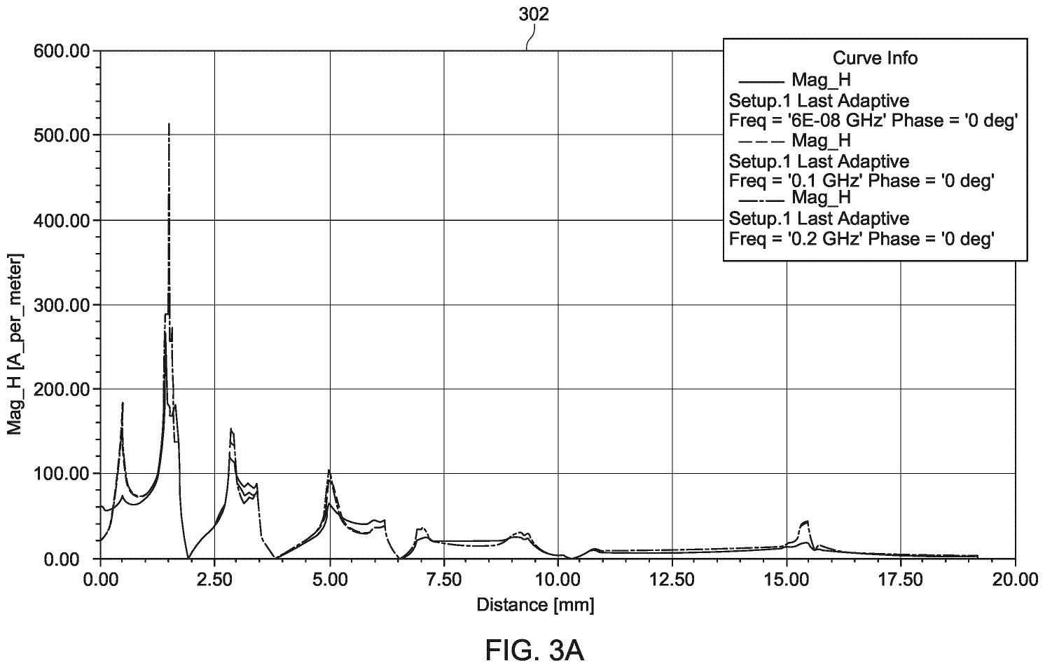

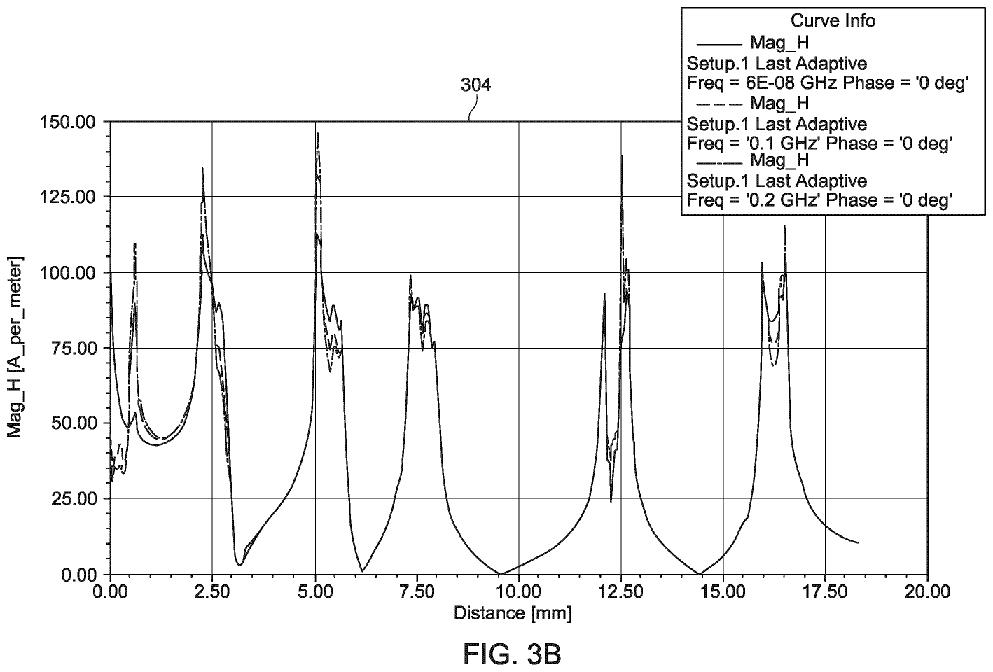

FIGS. 3A and 3B illustrate comparative plots of magnetic field strength (H) plotted along the X axis for the conventional spiral inductor 100 and the width modulated spiral inductor 200 respectively. The left plot 302 corresponding to the width-modulated spiral inductor 200 shows a peak flux of approximately 500 A/m in turn 2, i.e. the 0.003 m turn. The right plot 304 corresponding to the conventional spiral inductor 100 has relatively even flux distribution of approximately 125 A/m for each 0.006 m turn.

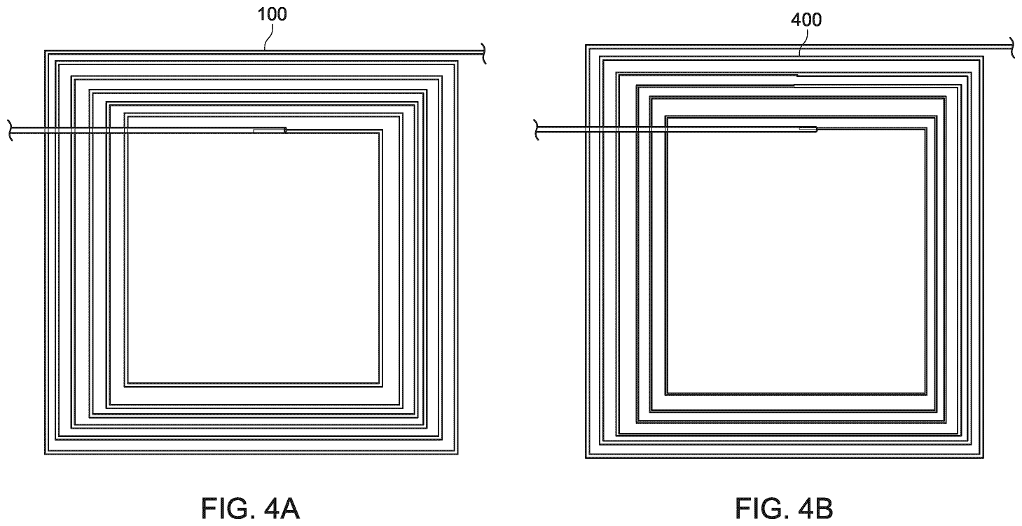

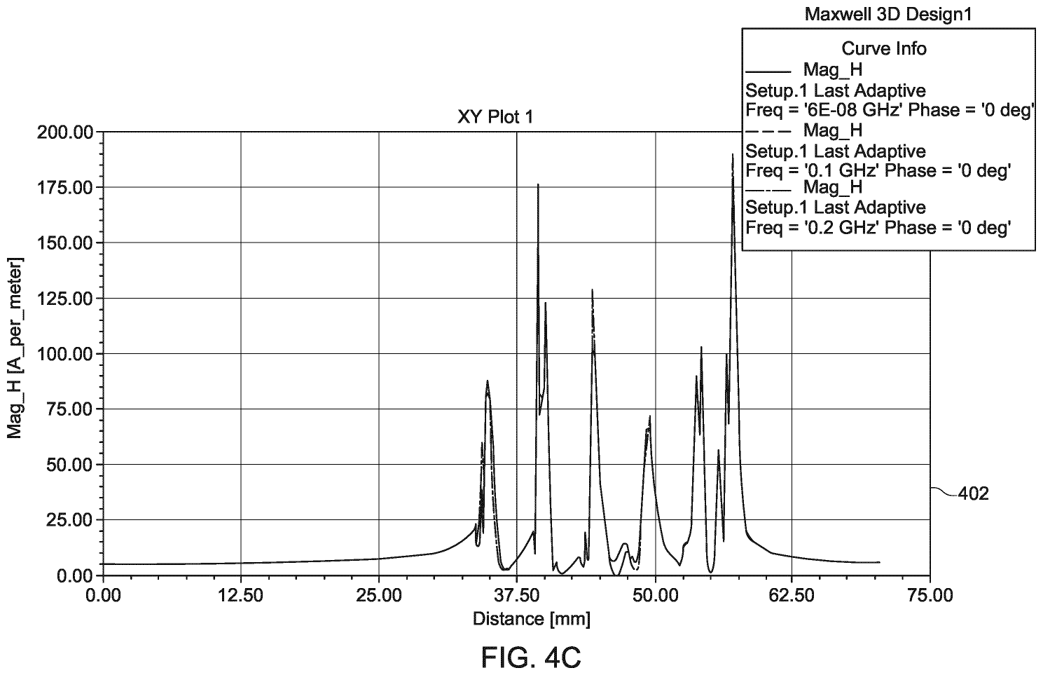

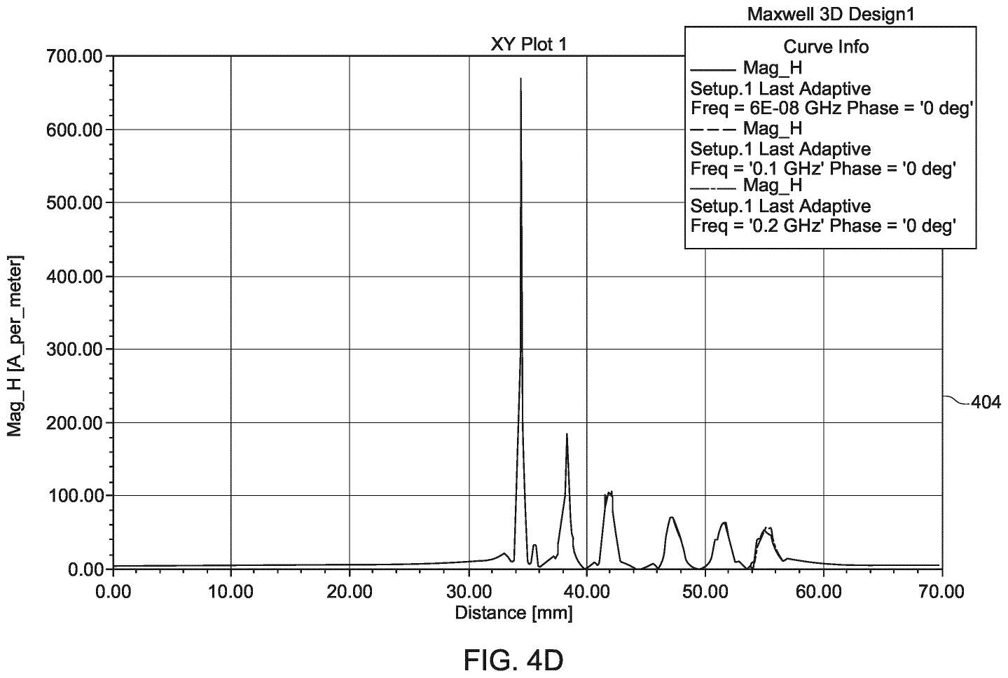

FIGS. 4A and 4B illustrate conventional spiral inductor 100 and more hollow width-modulated spiral inductor 400. FIGS. 4C and 4D illustrate comparative plot of magnetic field strength (H) plotted along the X axis for the conventional spiral inductor 100 and more hollow width-modulated spiral inductors 400. In the context of the present invention ‘more hollow’ is meant to mean that while the distance to or from the centre to the first coil remains the same, the modified-width coil has more turns accumulated as it travels into the coil.

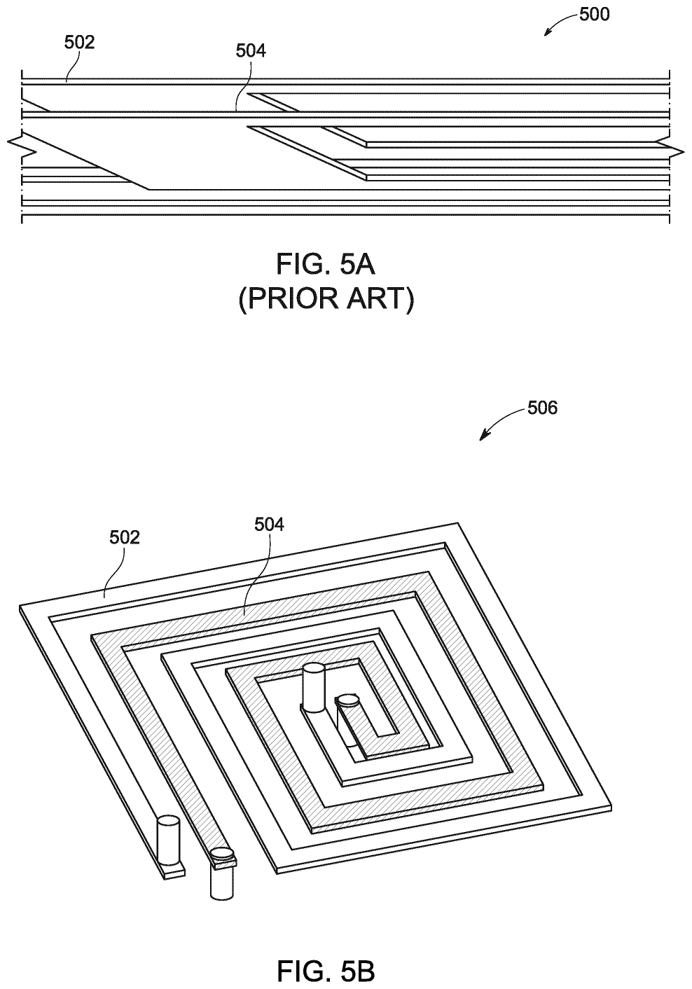

FIG. 5A illustrates a conventional spiral transformer 500 having a normal, vertical planar spiral transformer design. The conventional spiral transformer 500 includes primary and secondary inductors 502 and 504 placed on top of the other. In the context of this embodiment, each of the primary and secondary inductors 502 and 504 is similar to a conventional spiral planar inductor 100 (FIG. 1). The primary and secondary inductors 502 and 504 may be hereinafter also referred to as primary and secondary coils respectively.

FIG. 5B illustrates a first spiral transformer 506 in accordance with an embodiment of the present invention. The first spiral transformer 506 is formed of the primary and secondary inductors 502 and 504 in which the secondary inductor 504 does not sit directly below the primary inductor 502. The physical location of the secondary inductor 504 is at a secondary offset from the primary inductor 502. The offsetting the physical location of the secondary coil relative to the primary coil reduces primary to secondary capacitance between the primary and secondary coils, while not decreasing magnetic coupling to the same extent.

Below Table III provides a comparative analysis of parameters of the conventional spiral transformer 500 and the first spiral transformer 506.

TABLE III

| | Conventional | First |
|---|---|---|
| | transformer 500 | transformer 506 |
| Coupling factor | 80% | 23% |
| Coupling factor reduction | 0% | 71.3% |
| Primary to secondary | 3.49 | 0.18 |
| capacitance (pF) | | |
| Capacitance reduction | 0 | 94.8% |

As seen in Table III, when compared to the conventional transformer 500, the capacitance of the first transformer 506 is shown to be reduced by 94.8% while magnetic coupling is reduced by 71.3%. It is to be noted that the electric fields of a capacitor have less fringing capability than the magnetic fields of an inductor. An electric field follows the shortest distance between two charges, and a magnetic field curves back from whence it came. Therefore, when there is an offset between the primary and secondary coils, the electric field coupling would reduce far more than the magnetic field coupling.

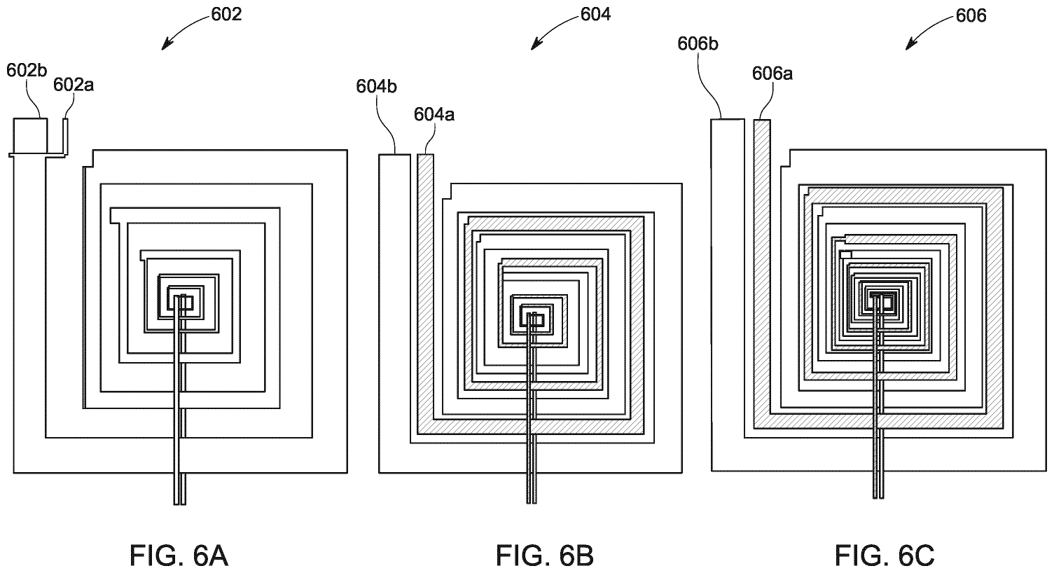

FIGS. 6A-6C illustrates second, third and fourth spiral transformers 602, 604 and 606 respectively, in accordance with other embodiments of the present invention. Each of the second, third and fourth spiral transformers 602, 604 and 606 are formed using width modulated inductors (explained in FIG. 2), and may be hereinafter also referred to as width-modulated transformer.

The second spiral transformer 602 is formed of a primary inductor 602a vertically stacked on top of a secondary inductor 602b in a conventional manner without an offset. Each of the primary and secondary inductors 602a and 602b is similar to the width-modulated spiral inductor 200 (FIG. 2) and are identical in their dimensions.

The third spiral transformer 604 is formed of a primary inductor 604a and a secondary inductor 604b, in which innermost three turns of the primary inductor 604a are vertically stacked on corresponding innermost three turns of the secondary inductor 604b, and outermost three turns of the primary inductor 604a are at an offset from corresponding outermost three turns of the secondary inductor 604b. Each of the primary and secondary inductors 604a and 604b are similar to the width-modulated spiral inductor 200 (FIG. 2) and are identical in their dimensions.

The fourth spiral transformer 606 is formed of a primary inductor 606a and a secondary inductor 606b, in which all the turns of the primary inductor 606a are at an offset from corresponding turns of the secondary inductor 606b. Each of the primary and secondary inductors 606a and 606b are similar to the width-modulated spiral inductor 200 (FIG. 2) and are identical in their dimensions.

Below Table IV provides a comparative analysis of parameters of the second, third and fourth transformers 602, 604 and 606.

TABLE IV

| | Second | Third | Fourth |
|---|---|---|---|
| | transformer | transformer | transformer |
| | 602 | 604 | 606 |
| Primary inductance (nH) | 675 | 648 | 647 |
| Coupling factor | 96% | 70% | 64% |
| Coupling factor reduction | 0% | 26.6% | 33.6% |
| Primary resistance (Ω) | 21.2 | 21 | 21.7 |
| Primary to secondary | 16.94 | 0.59 | 0.15 |
| capacitance (pF) | | | |
| Capacitance reduction | 0% | 96.5% | 99.1% |

It can be seen from Table IV that a 99% reduction in unwanted primary to secondary capacitance for a penalty of just a 33% reduction in magnetic coupling is achieved by the fourth transformer 606 in which all the turns of the primary and secondary coils are at an offset from each other.

It is to be noted that the transformers formed using width-modulated spiral inductor 200 has less side-to-side length between the primary and secondary coils as compared to transformers formed using conventional spiral planar inductor 100. By trying to fit N turns in a given area by using a constant width spiral it will take a longer piece of metal as compared to a narrower strip with the width-modulated inductor, in which more turns can be achieved further, and the width can be increased when proceeded outwards.

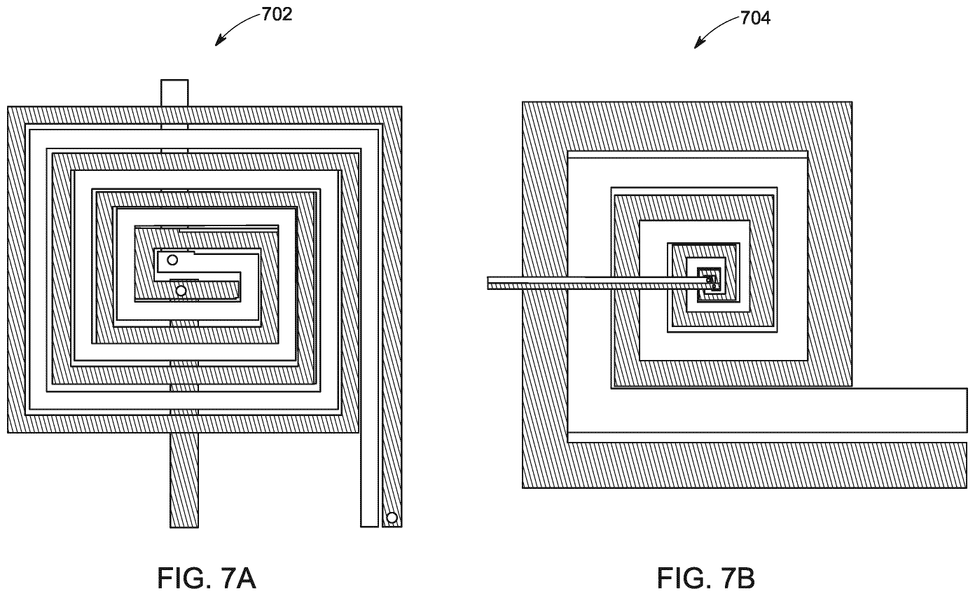

FIGS. 7A and 7B illustrate first and second transformers 702 and 704, in accordance with an embodiment of the present invention. The first transformer 702 is similar to the first spiral transformer 506 (explained in FIG. 5B) which includes two conventional spiral inductors 100 (explained in FIG. 1) that are at an offset from each other. The second transformer 704 is similar to the fourth transformer 606 (explained in FIG. 6) which includes two width-modulated spiral inductors 200 (explained in FIG. 2) that are at an offset from each other.

Below Table V illustrates simulated results comparing capacitance reduction using the first and second transformers 702 and 704. The dimensions of the first and second transformers 702 and 704 are 4 mm by 4 mm and frequency is 100 MHz.

TABLE V

| | First transformer 702 | Second transformer 704 |
|---|---|---|
| L(nH) | 38 | 21 |
| Coupling factor K | 68 | 66 |
| R(Ω) | 2.5 | 1.88 |
| C(pF) | 3.8 | 1.4 |
| L/R | 15.2 | 11.17 |
| L/C | 4.0 | 8.0 |

Based on the above table V, the trade off allowed by the second transformer 704 to maximize the ratio of desired inductance (L) to unwanted inter-winding capacitance (C) is seen.

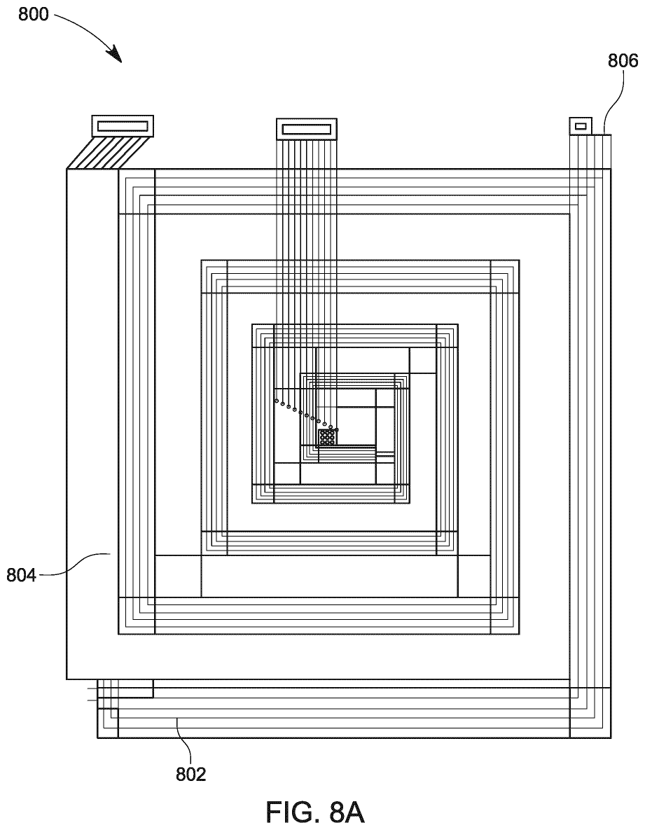

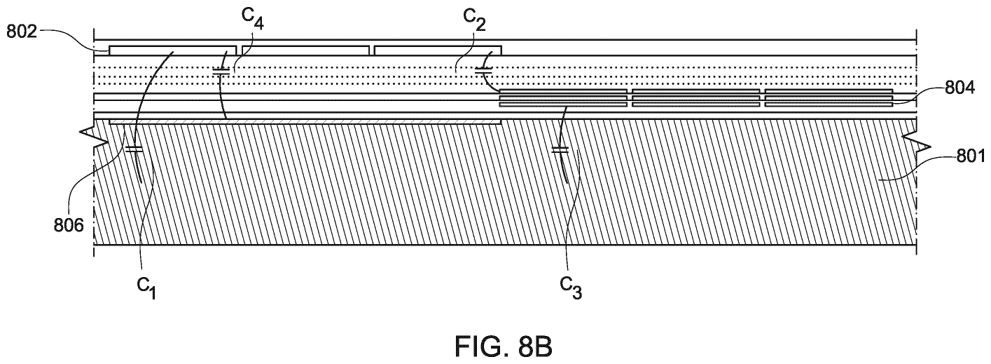

FIG. 8A illustrates a transformer 800 that includes two width-modulated spiral inductors 802 and 804 (similar to width-modulated spiral inductor 200, see FIG. 2) that are at an offset from each other, and a shield layer in the capacitance path of the inductors 802 and 804. FIG. 8B illustrates fabrication of the transformer 800 on a silicon substrate 801.

The width-modulated spiral inductors 802 and 804 form primary and secondary coils 802 and 804 respectively, and have an interleaved layout such that the lower coil (i.e. secondary coil 804) sits in the gaps between turns of the upper coil (i.e. primary coil 802). The primary coil 802 is made up of a thick metal top layer, and the secondary coil 804 is made from thick metal oxide layers. The IMD layers are inter-metal dielectrics.

In the absence of the shield layer 806, the capacitance between the primary and secondary coils 802 and 804 is the sum of C1, C2 and C3. C2 is direct parasitic capacitance between the primary and secondary coils 802 and 804, and is fringe capacitance. C1 and C3 forms a parasitic capacitance path from primary coil 802 down to the substrate 801, across the substrate 801 and then back up to the secondary coil 804.

In an embodiment of the present invention, the conductive shield layer 806 is provided beneath the level of both primary and secondary coils 802 and 804, to shield the capacitance path formed by C1 and C3. The shield layer 806 interact with the coils 802 and 804 to form a path across the transformer barrier, and act as a capacitance shield between the primary and secondary coils 802 and 804. The shield layer 806 prevents formation of the capacitance path (i.e C1+C3) from primary coil 802 down to the substrate 801, across the substrate 801 and then back up to the secondary coil 804. As a result, the capacitance between the primary and secondary coils 802 and 804 is C4 instead of C1 plus C3, where C4 is the capacitance from the primary coil 802 to the shield layer 806.

Since, the conductive shield layer 806 is provided at the substrate level, it can be made from a material other than metal. In an example, the conductive shield layer 806 may be formed by diffusing a layer pattern into the substrate 801 (like P+ or N+) which makes the diffused area conductive. The advantage of using a diffused layer as the shield layer 806 is that a metal layer is saved for use in the actual coil. Losing that metal layer would have led to higher resistance (so more power loss) in the coil.

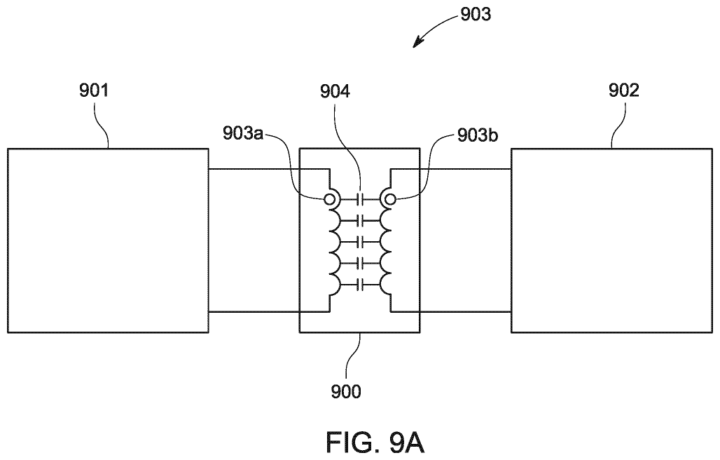

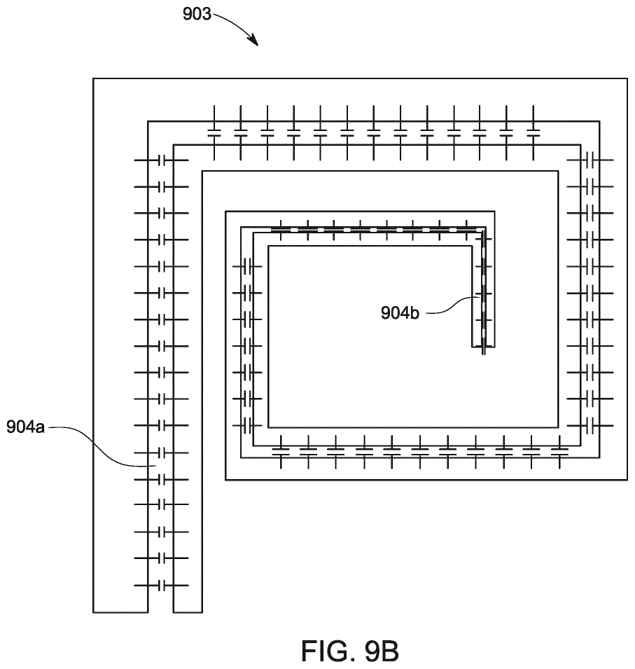

FIG. 9A illustrates a basic block diagram of a circuit 900 using a width-modulated transformer similar to the second transformer 704 (as explained in FIG. 7). The circuit 900 includes an AC drive 901, a primary coil 903a, a secondary coil 903b, and a rectifier 902. The primary and secondary coils 903a and 903b form the width modulated transformer. The rectifier 902 rectifies the AC signal to recover the signal or power carried across the width modulated transformer. There is an inter-winding capacitance 904 that exists between the primary and secondary coils 903a and 903b, which is normally undesired for many reasons. A major reason is it would couple a common mode noise signal across the width-modulated transformer that would otherwise have been blocked as it was equipotential on both terminals of the primary coil 903a. If the interwinding capacitance 904, is evenly spread, i.e. symmetric, along the entire length of the two coils, the unwanted common mode signal appears as an equal common mode signal viewed at either end of the secondary coil 903b. It may then be dealt with, using a differential amplifier.

However, if the capacitance is unevenly spread, i.e. asymmetric, this noise signal will be larger on one side of the secondary coil 903b and will get through the rectifier as an error signal. It is very likely that with the use of width modulated transformer, the capacitance would be unevenly spread because the primary to secondary coils 903a and 903b would not be of same area and at same distance from each other throughout the entire winding lengths.

FIG. 9B illustrates a diagrammatic representation of inter-winding capacitance varying with track to track space in physical layout of the width-modulated transformer 903, in accordance with an embodiment of the present invention.

In an embodiment of the present invention, the track to track space can be varied throughout the length of the transformer 903. A wider track to track space may decrease the inter-winding capacitance 904a and 904b in that zone and vice versa. This action allows a designer to modulate the inter-winding capacitance 904a and 904b as a method of keeping it symmetric throughout. This may allow the designer to overcome the problem of common mode transients caused by asymmetric capacitance as outlined above in FIG. 9A.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A transformer comprising:
a primary spiral inductor; and
a secondary spiral inductor magnetically coupled to the primary spiral inductor, wherein a physical location of the secondary spiral inductor is at an offset relative to the primary spiral inductor to reduce interwinding capacitance between the primary and secondary spiral inductors, while decreasing a magnetic coupling between the primary and secondary spiral inductors to a lesser extent.

2. The transformer as claimed in claim 1, wherein the primary and secondary spiral inductors are spaced apart and stacked vertically in a staggered manner, such that at least one turn of the primary spiral inductor does not overlap with at least one turn of the secondary spiral inductor.

3. The transformer as claimed in claim 1, wherein each of the primary and secondary spiral inductors is a constant-width spiral inductor, wherein the constant-width spiral inductor includes a plurality of turns of a constant width.

4. The transformer as claimed in claim 1, wherein each of the primary and secondary spiral inductors is a width-modulated spiral inductor, wherein the width-modulated spiral inductor includes a plurality of turns arranged in a substantially planar manner, and wherein each turn has a width different from a width of another turn.

5. The transformer as claimed in claim 4, wherein the primary and secondary spiral inductors are fabricated as top and bottom layers respectively on a silicon substrate, in a manner such that the secondary spiral inductor sits in one or more gaps between turns of the primary spiral inductor, and wherein a conductive shield layer is provided beneath the primary and secondary spiral inductors, to prevent formation of a capacitance path from the primary spiral inductor down to the silicon substrate, across the silicon substrate and then back up to the secondary spiral inductor.

6. The transformer as claimed in claim 5, wherein the primary spiral inductor is formed from a thick metal layer, the secondary spiral inductor coil is formed from thick metal oxide layers, and the conductive shield layer is formed by diffusing one of p and n layers into the silicon substrate.

7. The transformer as claimed in claim 4, wherein a first turn of the plurality of turns has a predefined length and width, and a length and width of each turn subsequent to the first turn is obtained by multiplying a length and a width of corresponding previous turn by a predetermined ratio, such that resistance-per-turn of the width-modulated spiral inductor remains constant.

8. The transformer as claimed in claim 4, wherein variable width of the plurality of turns modulates a ratio of overall inductance to overall resistance of the width-modulated spiral inductor.

9. The transformer as claimed in claim 4, wherein a pre-defined number of inner turns of the plurality of turns have a width smaller than a pre-defined average width, and a pre-defined number of outer turns of the plurality of turns have a width greater than the pre-defined average width.

10. The transformer as claimed in claim 4, wherein magnetic field strength of the width-modulated spiral inductor is unevenly distributed across the plurality of turns, to concentrate magnetic flux density of the width-modulated spiral inductor across a pre-defined number of turns.

11. The transformer as claimed in claim 10, wherein width of each turn and the offset between the primary and secondary spiral inductors is determined so as to maximise the magnetic flux density and minimize capacitive coupling across the pre-defined number of turns.

12. The transformer as claimed in claim 1, wherein a track to track space between the primary and secondary spiral inductors is modulated along a length of the transformer to enable even spread of the interwinding capacitance along the length of the transformer.
